(19) United States
(12) Patent Application Publication
(10) Pub. No.: US 2024/0004474 A1
(43) Pub. Date: Jan. 4, 2024

(54) FILM DEFORMATION ELEMENT, HAPTIC FEEDBACK UNIT AND HAPTIC FEEDBACK SYSTEM

(71) Applicant: Industrial Technology Research Institute, Hsinchu (TW)

(72) Inventors: Chen-Tsai Yang, Taoyuan City (TW); Heng-Yin Chen, Hsinchu County (TW); Wan-Chen Yang, New Taipei City (TW); Jui-Chang Chuang, Kaohsiung City (TW); Hung-Hsien Ko, Hsinchu County (TW); Min-Hsiung Liang, Hsinchu County (TW); Chih-Cheng Cheng, Taichung City (TW)

(73) Assignee: Industrial Technology Research Institute, Hsinchu (TW)

(21) Appl. No.: 18/343,760

(22) Filed: Jun. 29, 2023

Related U.S. Application Data
(60) Provisional application No. 63/356,500, filed on Jun. 29, 2022.

(30) Foreign Application Priority Data
May 30, 2023 (TW) 112120058

(51) Int. Cl. G06F 3/01; H10N 30/20; H10N 30/88; H10N 30/80

(52) U.S. Cl. CPC G06F 3/016; H10N 30/20; H10N 30/88; H10N 30/802

(57) ABSTRACT

A film deformation element includes a first stack and a second stack. The first stack includes a first passivation layer, a first substrate, a first metal layer and a first dielectric layer. The first substrate is disposed on the first passivation layer. The first metal layer is disposed on the first substrate. The first dielectric layer is disposed on the first metal layer. The second stack is bonded to the first stack, to form a sealing space. The second stack includes a second passivation layer, a second substrate, a second metal layer and a second dielectric layer. The second dielectric layer is disposed on and faces the first dielectric layer. The second metal layer is disposed on the second dielectric layer. The second substrate is disposed on the second metal layer. The second passivation layer is disposed on the second substrate.

### CROSS-REFERENCE TO RELATED APPLICATION

This application claims the priority benefit of U.S. provisional application Ser. No. 63/356,500, filed on Jun. 29, 2022 and Taiwan Application No. 112120058, filed on May 30, 2023. The entirety of each of the above-mentioned patent applications is hereby incorporated by reference herein and made a part of this specification.

### TECHNICAL FIELD

The disclosure relates to a deformation element, a feedback unit and a feedback system, and also relates to a film deformation element, a haptic feedback unit and a haptic feedback system.

### BACKGROUND

In response to the outbreak of the epidemic, the new normal life after the epidemic will expand the contactless digital economy and accelerate industrial transformation, and smart applications with vertical configuration will develop towards virtual-real interaction, immersive experience, and sensing services. However, the existing haptic feedback gloves only have a single feedback function, which cannot provide more realistic feedback.

### SUMMARY

According to an embodiment of the disclosure, a film deformation element includes a first stack and a second stack. The first stack includes a first passivation layer, a first substrate, a first metal layer and a first dielectric layer. The first substrate is disposed on the first passivation layer. The first metal layer is disposed on the first substrate. The first dielectric layer is disposed on the first metal layer. The second stack is bonded to the first stack, to form a sealing space. The second stack includes a second passivation layer, a second substrate, a second metal layer and a second dielectric layer. The second dielectric layer is disposed on and faces the first dielectric layer. The second metal layer is disposed on the second dielectric layer. The second substrate is disposed on the second metal layer. The second passivation layer is disposed on the second substrate.

According to an embodiment of the disclosure, a haptic feedback unit includes a film deformation element and a piezoelectric vibration element. The film deformation element includes a first stack and a second stack oppositely disposed, wherein the first stack and the second stack respectively include a first passivation layer, a first substrate, a first metal layer and a first dielectric layer. The piezoelectric vibration element includes a support layer, a second passivation layer and a mass damping layer.

According to an embodiment of the disclosure, a haptic feedback system includes at least one haptic feedback unit, a sensing signal device, and a control module for multi-haptic feedback film device. The sensing signal device is electrically connected to the at least one haptic feedback unit. The control module for multi-haptic feedback film device is electrically connected to the at least one haptic feedback unit.

Several exemplary embodiments accompanied with figures are described in detail below to further describe the disclosure in details.

### BRIEF DESCRIPTION OF THE DRAWINGS

FIG. 1A to FIG. 1D are schematic cross-sectional views of a flow of a manufacturing method of a film deformation element according to an embodiment of the disclosure, and FIG. 1E is a schematic view of an actuation of the film deformation element of FIG. 1D.

FIG. 2A to FIG. 2H are schematic top views of a film deformation element according to an embodiment of the disclosure.

FIG. 3A is a schematic cross-sectional view of a haptic feedback unit according to an embodiment of the disclosure, FIG. 3B is a schematic bottom view of FIG. 3A, and FIG. 3C is a schematic view of an actuation of the haptic feedback unit of FIG. 3A.

FIG. 4A to FIG. 4C are schematic cross-sectional views of a haptic feedback unit according to an embodiment of the disclosure.

FIG. 5A is a schematic cross-sectional view of a haptic feedback unit according to an embodiment of the disclosure, and FIG. 5B is a schematic view of an actuation of the haptic feedback unit of FIG. 5A.

FIG. 6A is a schematic cross-sectional view of a haptic feedback unit according to an embodiment of the disclosure, and FIG. 6B is a schematic view of an actuation of the haptic feedback unit in FIG. 6A.

FIG. 7A is a schematic cross-sectional view of a haptic feedback unit according to an embodiment of the disclosure, and FIG. 7B is a partial schematic top view of FIG. 7A.

FIG. 8A is a schematic cross-sectional view of a haptic feedback unit according to an embodiment of the disclosure, and FIG. 8B is a partial schematic top view of FIG. 8A.

FIG. 9A to FIG. 9D are schematic views of a haptic feedback device according to an embodiment of the disclosure.

FIG. 10 is a schematic view of a haptic feedback system according to an embodiment of the disclosure.

FIG. 11 is a schematic view of a haptic feedback system according to an embodiment of the disclosure.

FIG. 12 is a schematic view of a haptic feedback system according to an embodiment of the disclosure.

FIG. 13 is a graph showing the relationship between air pressure and displacement of a film deformation element according to an embodiment of the disclosure.

### DESCRIPTION OF THE EMBODIMENTS

The following are examples of the contents of the disclosure described in detail. The implementation details provided in the embodiments are for illustration purposes, and are not intended to limit the scope of protection of the disclosure. Anyone with ordinary knowledge in the technical field may modify or change the above-mentioned implementation details according to actual implementation requirements.

In this article, terms such as “comprising”, “including”, and “having” are all open terms, which means “including but not limited to”.

Also, herein, a range expressed by “one value to another value” is a general representation to avoid enumerating all values in the range in the specification. Thus, the recitation of a particular numerical range encompasses any numerical value within that numerical range, as well as smaller numerical ranges bounded by any numerical value within that numerical range.

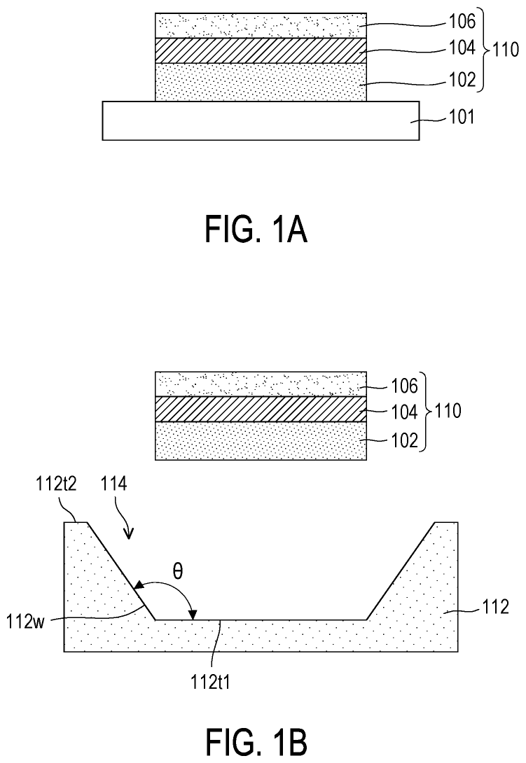

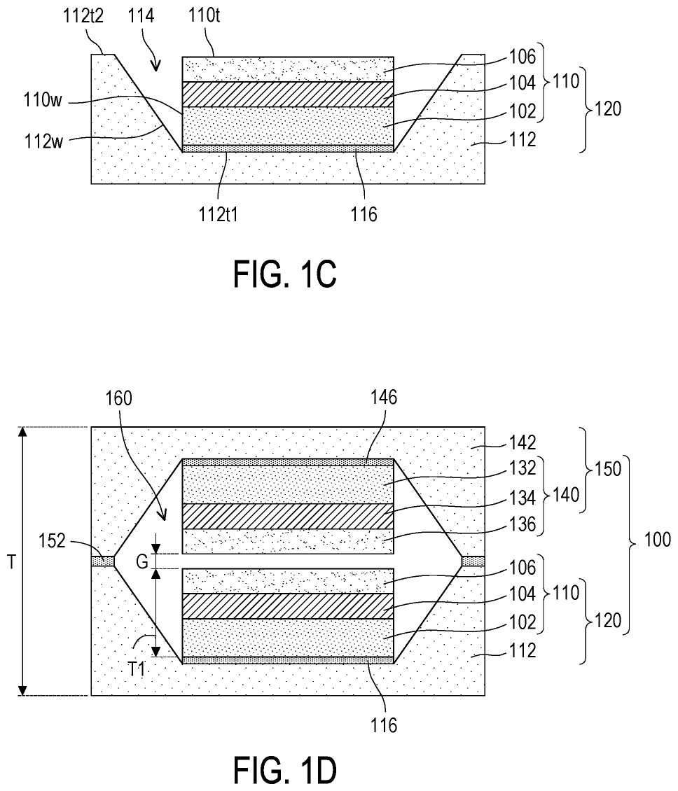

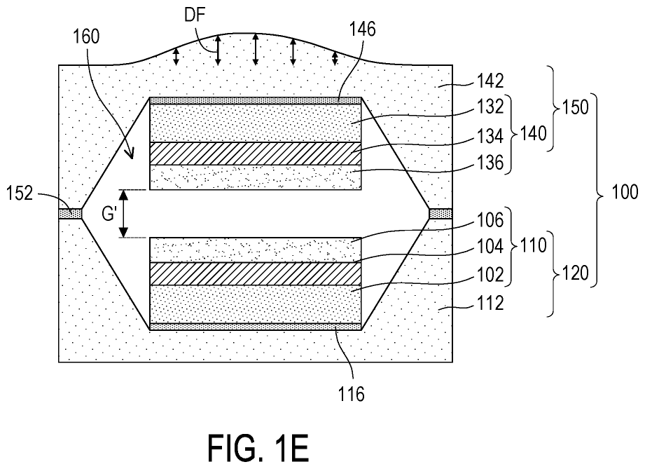

FIG. 1A to FIG. 1D are schematic cross-sectional views of a flow of a manufacturing method of a film deformation element according to an embodiment of the disclosure, and FIG. 1E is a schematic view of an actuation of the film deformation element of FIG. 1D.

Referring to FIG. 1A, firstly, a first substrate 102 is formed on a carrier 101. The carrier 101 is, for example, a glass substrate or other suitable substrate capable of carrying a film. In this embodiment, the material of the first substrate 102 is, for example, polyimide (PI), polyethylene (PE), polypropylene (PP), polyvinyl chloride (PVC), polyethylene terephthalate polyester (PET), polystyrene (PS), polycarbonate (PC), the like or a combination thereof. The first substrate 102 can be formed by deposition such as chemical vapor deposition or physical vapor deposition, coating or other suitable methods.

Next, a first metal layer 104 is formed on the first substrate 102. In this embodiment, the material of the first metal layer 104 can be Cu, Ti, Mo, Au, Ag, Al, the like or a combination thereof. In one embodiment, the first metal layer 104 is, for example, silver paste, copper paste, nickel paste, or a combination thereof. The first metal layer 104 can be formed by deposition such as chemical vapor deposition or physical vapor deposition, electroplating or other suitable methods.

Then, a first dielectric layer 106 is formed on the first metal layer 104. In this embodiment, the material of the first dielectric layer 106 can be a dielectric material with a dielectric constant of 1-100. In one embodiment, the material of the first dielectric layer 106 can be a high dielectric constant (high-k) dielectric material, such as Y₂O₃, Y₂TiO₅, Yb₂O₃, HfO₂, ZrO₂, TiO₂, Si₃N₄, Al₂O₃, Y₂O₃, Ta₂O₅, the like or a combination thereof. The first dielectric layer 106 can be formed by deposition such as chemical vapor deposition or physical vapor deposition, coating or other suitable methods. In this embodiment, sidewalls of the first substrate 102, the first metal layer 104, and the first dielectric layer 106 are, for example, substantially flush. However, the disclosure is not limited thereto. In another embodiment, the sidewalls of at least two of the first substrate 102, the first metal layer 104, and the first dielectric layer 106 are not substantially flush. In this embodiment, the first substrate 102, the first metal layer 104 and the first dielectric layer 106 are collectively referred to as a first function structure 110.

Referring to FIG. 1B and FIG. 1C, next, the first function structure 110 including the first substrate 102, the first metal layer 104 and the first dielectric layer 106 is bonded to a first passivation layer 112, to form a first stack 120. In this embodiment, as shown in FIG. 1B, before the first function structure 110 is bonded to the first passivation layer 112, the first function structure 110 is separated from the carrier 101 and the first passivation layer 112 is provided. In this embodiment, the first passivation layer 112 has a housing space 114, for example. Specifically, an upper surface of the first passivation layer 112 includes a surface 112t1 and a surface 112t2 higher than the surface 112t1. In this embodiment, the housing space 114 is composed of an inner sidewall 112w of the first passivation layer 112 and the surface 112t1. In this embodiment, the inner sidewall 112w of the first passivation layer 112 is, for example, inclined. Specifically, an angle θ formed between the inner sidewall 112w and the surface 112t1 of the first passivation layer 112 is, for example, greater than 90 degrees. However, the disclosure is not limited thereto. In another embodiment, the inner sidewall 112w of the first passivation layer 112 is substantially vertical, that is, the angle θ formed between the inner sidewall 112w and the surface 112t1 of the first passivation layer 112 is, for example, about 90 degrees. The material of the first passivation layer 112 includes polydimethylsiloxane (PDMS), trimethylsiloxy group (Si—SH₃), hexamethyldisiloxane (HMDSO), the like or a combination thereof. In this embodiment, the first passivation layer 112 is made through a mold, for example. However, the disclosure is not limited thereto. The first passivation layer 112 can also be made in other suitable ways.

In this embodiment, as shown in FIG. 1C, the first function structure 110 is bonded to the first passivation layer 112 by gluing or engagement, for example. In one embodiment, as shown in FIG. 1C, the first function structure 110 is bonded to the surface 112t1 of the first passivation layer 112 through an adhesion layer 116, for example. In this embodiment, the material of the adhesion layer 116 includes acrylic adhesive, rubber adhesive, the like or a combination thereof. In this embodiment, the first function structure 110 is placed in the housing space 114 of the first passivation layer 112. Therefore, the first substrate 102, the first metal layer 104 and the first dielectric layer 106 are sequentially stacked on the surface 112t1 of the first passivation layer 112, for example. In this embodiment, a sidewall 110w of the first function structure 110 (such as a sidewall of the first substrate 102) is separated from the inner sidewall 112w of the first passivation layer 112 by the housing space 114. In this embodiment, as shown in FIG. 1C, the uppermost surface 110t of the first function structure 110 is, for example, not higher than the uppermost surface 112t2 of the first passivation layer 112.

Referring to FIG. 1D, and then, a second stack 150 is provided. Next, the second stack 150 is bonded to the first stack 120 to form a film deformation element 100. In this embodiment, the second stack 150 has a similar structure to the first stack 120, for example. Specifically, the second stack 150 includes, for example, a second passivation layer 142 and a second function structure 140 composed of a second substrate 132, a second metal layer 134 and a second dielectric layer 136. The second substrate 132, the second metal layer 134, the second dielectric layer 136, and the second passivation layer 142 are, for example, similar to the aforementioned first substrate 102, the aforementioned first metal layer 104, the aforementioned first dielectric layer 106, and the aforementioned first passivation layer 112, respectively, so it will not be repeatedly described here. In this embodiment, the second function structure 140 is bonded to a surface of the second passivation layer 142 through an adhesion layer 146, and thus the second function structure 140 is disposed in a housing space of the second passivation layer 142. In this embodiment, sidewalls of the second substrate 132, the second metal layer 134, and the second dielectric layer 136 are, for example, substantially flush. However, the disclosure is not limited thereto. In another embodiment, the sidewalls of at least two of the second substrate 132, the second metal layer 134, and the second dielectric layer 136 are not substantially flush.

In this embodiment, the first stack 120 and the second stack 150 are bonded through an adhesion layer 152, for example. In this embodiment, the material of the adhesion layer 152 includes acrylic adhesive, rubber adhesive, the like or a combination thereof. For example, the first passivation layer 112 and the second passivation layer 142 are aligned and attached to each other through the adhesion layer 152, so that the first stack 120 and the second stack 150 are bonded. As shown in FIG. 1D, after the second stack 150 is bonded to the first stack 120, in the vertical direction, the second dielectric layer 136 is, for example, disposed on the first dielectric layer 106 and faces the first dielectric layer 106. The second metal layer 134 is disposed on the second dielectric layer 136, the second substrate 132 is disposed on the second metal layer 134, and the second passivation layer 142 is disposed on the second substrate 132, for example. In this embodiment, the sidewalls of the first substrate 102, the first metal layer 104, the first dielectric layer 106, the second substrate 132, the second metal layer 134, and the second dielectric layer 136 are substantially flush, for example. Additionally, sidewalls of the first passivation layer 112 and the second passivation layer 142 are, for example, substantially flush. However, the disclosure is not limited thereto. In this embodiment, after the first stack 120 and the second stack 150 are bonded, a sealing space 160 is formed between the first stack 120 and the second stack 150, and the sealing space 160 is filled with air, for example. In this embodiment, after the first stack 120 and the second stack 150 are bonded, the first function structure 110 and the second function structure 140 are separated from each other by, for example, a distance G. In other words, the first dielectric layer 106 and the second dielectric layer 136 are physically separated from each other without contacting.

In this embodiment, the thickness T1 of the first function structure 110 or the second function structure 140 is, for example, between 2 μm and 800 μm, and the Young's coefficient of the first function structure 110 or the second function structure 140 (also called an equivalent Young's modulus of three-layer structure of substrate/metal layer/dielectric layer) is, for example, 0.001-169. In one embodiment, the thickness T1 of the first function structure 110 or the second function structure 140 is, for example, 50 μm, and the Young's modulus of the first function structure 110 or the second function structure 140 is, for example, 20. The total thickness T of the first passivation layer 112 and the second passivation layer 142 (that is, the total thickness of the film deformation element 100) is, for example, 25 μm-400 μm, and the Young's modulus of the first passivation layer 112 and the second passivation layer 142 is, for example, 0.01-2.2. In one embodiment, the total thickness T of the first passivation layer 112 and the second passivation layer 142 is, for example, 250 μm, and the Young's modulus of the first passivation layer 112 and the second passivation layer 142 is, for example, 1. In this embodiment, the ratio of the thickness T1 of the first function structure 110 or the second function structure 140 to the total thickness T of the passivation layer 112 and 142 is, for example, 0.005-32. In one embodiment, the thickness ratio is, for example, 1/5. In this embodiment, the ratio of the Young's modulus of the first function structure 110 or the second function structure 140 to the Young's modulus of the passivation layer 112 and 142 is, for example, 0.00045-16900. In an embodiment, the Young's modulus ratio is 20, for example.

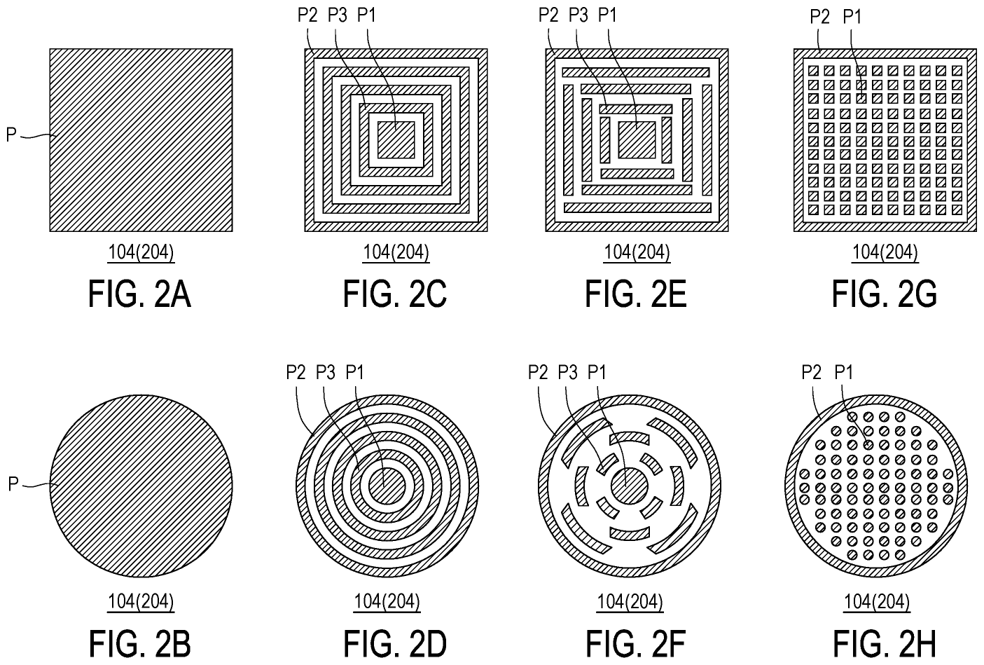

A schematic top view of at least one of the first metal layer 104 and the second metal layer 134 can be a square (as shown in FIG. 2A), a circle (as shown in FIG. 2B), multiple concentric square rings (as shown in FIG. 2C), multiple concentric circular rings (as shown in FIG. 2D), a square spiral composed of multiple segments (as shown in FIG. 2E), a circular spiral composed of multiple segments (as shown in FIG. 2F), or a plurality of patterns arranged in an array (as shown in FIG. 2G and FIG. 2H) or a combination thereof. In the embodiment shown in FIG. 2A and FIG. 2B, at least one of the first metal layer 104 and the second metal layer 134 includes a single pattern (also called a full pattern) P. In the embodiment shown in FIG. 2C to FIG. 2F, at least one of the first metal layer 104 and the second metal layer 134 includes a first pattern (also called inner pattern) P1, a second pattern (also called outer pattern) P2 and at least one third pattern (also called intermediate pattern) P3 between the first pattern P1 and the second pattern P2. In detail, as shown in FIG. 2C, the first pattern P1 can be a square, and the second pattern P2 and the third patterns P3 can be concentric square rings surrounding the first pattern P1 respectively. As shown in FIG. 2D, the first pattern P1 can be a circle, and the second pattern P2 and the third patterns P3 can be concentric rings surrounding the first pattern P1 respectively. As shown in FIG. 2E, the first pattern P1 can be a square, the second pattern P2 can be a square ring surrounding the first pattern P1, and the third patterns P3 can be strip patterns arranged into a plurality of concentric square rings. As shown in FIG. 2F, the first pattern P1 can be a circle, the second pattern P2 can be a ring surrounding the first pattern P1, and the third patterns P3 can be arc-shaped patterns arranged in multiple concentric rings. In the embodiment shown in FIG. 2G and FIG. 2H, at least one of the first metal layer 104 and the second metal layer 134 includes a plurality of first patterns (also called inner patterns or particle patterns) P1 and a second pattern (also known as outer pattern) P2 surrounding the first patterns P1. In detail, as shown in FIG. 2G, the first pattern P1 can be a square, and the first patterns P1 can be arranged in an array, and the second pattern P2 can be a square ring. As shown in FIG. 2H, the first pattern P1 can be a circle, and the first patterns P1 can be arranged in an array, and the second pattern P2 can be a circular ring. However, the disclosure is not limited thereto. The first metal layer 104 and the second metal layer 134 can be of any suitable size, shape or number.

In this embodiment, when there is no voltage, as shown in FIG. 1D, a gap G is formed between the first function structure 110 and the second function structure 140 of the film deformation element 100, and when there is a voltage, as shown in FIG. 1E, the second passivation layer 142 of the second function structure 140 can generate a vertical deformation DF, and there is an increased distance G′ between the first function structure 110 and the second function structure 140. In other words, the film deformation element 100 can provide vertical deformation. In this embodiment, the second passivation layer 142 of the second function structure 140 deforms upwards, but in other embodiments, the first passivation layer 112 of the first function structure 110 can deform downwards. In other words, at least one of the second passivation layer 142 of the function structure 140 and the first passivation layer 112 of the first function structure 110 can deform.

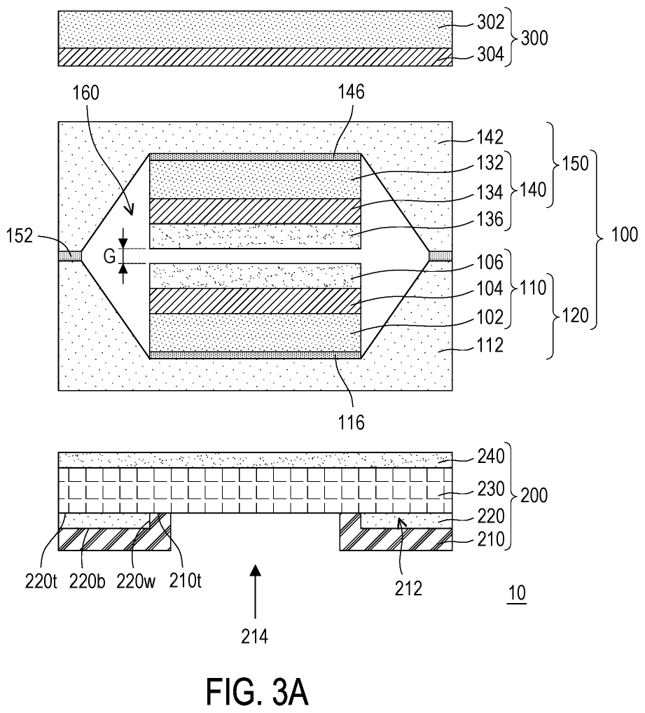

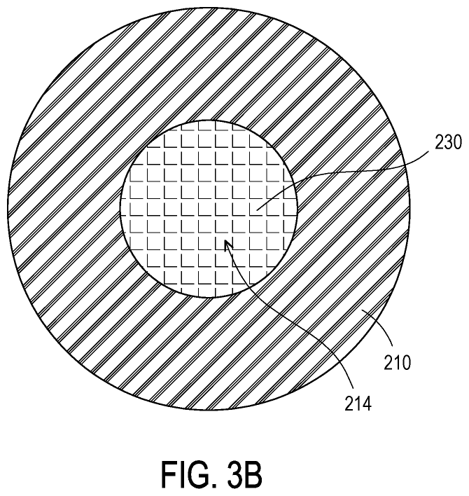

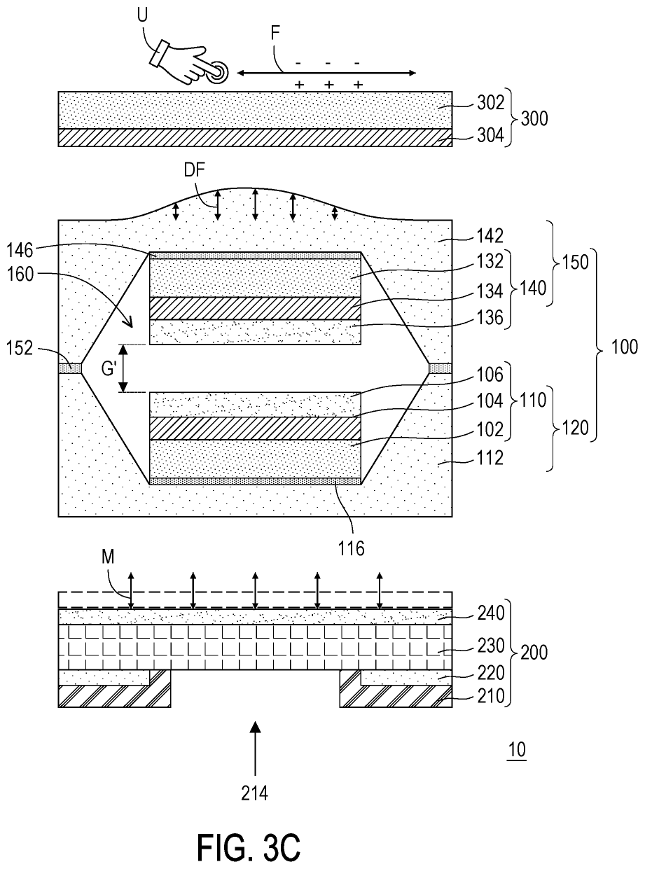

FIG. 3A is a schematic cross-sectional view of a haptic feedback unit according to an embodiment of the disclosure, FIG. 3B is a schematic bottom view of FIG. 3A, and FIG. 3C is a schematic view of an actuation of the haptic feedback unit of FIG. 3A.

Referring to FIG. 3A and FIG. 3B, in this embodiment, the haptic feedback unit 10 is a vertically stacked structure, and includes a film deformation element 100, a piezoelectric vibrating element 200 and a micro-electric stimulation element 300. In this embodiment, the film deformation element 100 is disposed between the micro-electric stimulation element 300 and the piezoelectric vibration element 200, that is, the piezoelectric vibration element 200 and the micro-electric stimulation element 300 are disposed on opposite sides (such as lower side and upper side) of the film deformation element 100. The piezoelectric vibration element 200 includes, for example, a support layer 210, a passivation layer 220, a mass damping layer 230 and a dielectric layer 240. In this embodiment, the passivation layer 220 is, for example, sandwiched between the mass damping layer 230 and the support layer 210. The mass damping layer 230 is, for example, disposed between the dielectric layer 240 and the support layer 210, and between the dielectric layer 240 and the passivation layer 220. For example, the passivation layer 220, the mass damping layer 230 and the dielectric layer 240 are sequentially disposed on the support layer 210.

The support layer 210 is, for example, ring-shaped, that is, as shown in FIG. 3A and FIG. 3B, the support layer 210 has a housing space 212 and a hole 214. The housing space 212 is, for example, used to house the passivation layer 220, and the hole 214 is, for example, exposing the mass damping layer 230 thereabove. The support layer 210 can be a polymer frame. The passivation layer 220 is disposed on the support layer 210 and is, for example, disposed in the housing space 212 of the support layer 210. In this embodiment, an inner sidewall 220w and a bottom surface 220b of the passivation layer 220 are in physical contact with the support layer 210 respectively, for example. The passivation layer 220 can be ring-shaped, so that the passivation layer 220 together with the support layer 210 exposes the mass damping layer 230 thereabove. In this embodiment, an upper surface 210t of the support layer 210 and an upper surface 220t of the passivation layer 220 are substantially coplanar. The material of the passivation layer 220 includes polydimethylsiloxane (PDMS), trimethylsiloxy group (Si—SH₃), hexamethyldisiloxane (HMDSO), the like or a combination thereof. The mass damping layer 230 is, for example, disposed on the passivation layer 220 and the support layer 210. The mass damping layer 230 is, for example, a metal block, and the material of the metal block includes copper, iron, mercury, the like or a combination thereof. The dielectric layer 240 is, for example, disposed on the mass damping layer 230. The material of the dielectric layer 240 can be a high-k material, such as Y₂O₃, Y₂TiO₅, Yb₂O₃, HfO₂, ZrO₂, TiO₂, Si₃N₄, Al₂O₃, Y₂O₃, Ta₂O₅, the like or a combination thereof. In this embodiment, outer sidewalls of the support layer 210, the passivation layer 220, the mass damping layer 230 and the dielectric layer 240 are, for example, flush. However, the disclosure is not limited thereto. In other embodiments, the hole 214 may also be filled with suitable materials.

In this embodiment, the micro-electric stimulation element 300 is disposed above the film deformation element 100 and the piezoelectric vibration element 200, for example. That is, the micro-electric stimulation element 300 is, for example, disposed on the outermost surface of the haptic feedback unit 10 and can be used for direct contact with the wearer. The micro-electric stimulation element 300 includes, for example, a substrate 302 and a metal layer 304 disposed at one side of the substrate 302. In this embodiment, the substrate 302 faces outward, and the metal layer 304 faces the film deformation element 100, that is, the metal layer 304 is disposed between the substrate 302 and the film deformation element 100. The material of the substrate 302 is, for example, polyimide (PI), polyethylene (PE), polypropylene (PP), polyvinyl chloride (PVC), polyethylene terephthalate (PET), polystyrene Vinyl (PS), polycarbonate (PC), the like or a combination thereof. The formation method of the substrate 302 can be deposition such as chemical vapor deposition or physical vapor deposition, coating or other suitable methods. The material of the metal layer 304 can be Cu, Ti, Mo, Au, Ag, Al, the like or a combination thereof. The formation method of the metal layer 304 can be deposition such as chemical vapor deposition or physical vapor deposition, electroplating or other suitable methods. In one embodiment, as shown in FIG. 3C, the metal layer 304 of the micro-electric stimulation element 300 is, for example, grounded.

Referring to FIG. 3C, in this embodiment, a horizontal friction force F is generated through the electrostatic force between the micro-electric stimulation element 300 and the user (i.e. the human body) U (for example, in FIG. 3C, “−” means that the finger is negatively charged, and “+” means that the surface of the substrate 302 is positively charged). Thus, the film deformation element 100 can provide vertical deformation DF, and the piezoelectric vibration element 200 can generate simple harmonic vibration M with various frequencies. That is, the haptic feedback unit 10 is a multi-haptic film structure, which includes three kinds of haptic sensing elements that can be vertically stacked through film manufacturing process, thereby increasing the space density of haptic types. Therefore, the haptic feedback unit 10 can also be called a multi-haptic feedback unit.

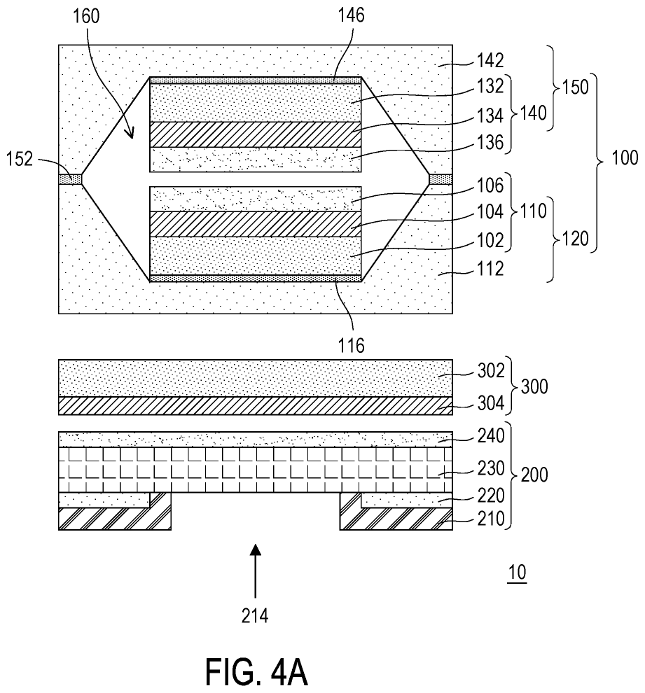

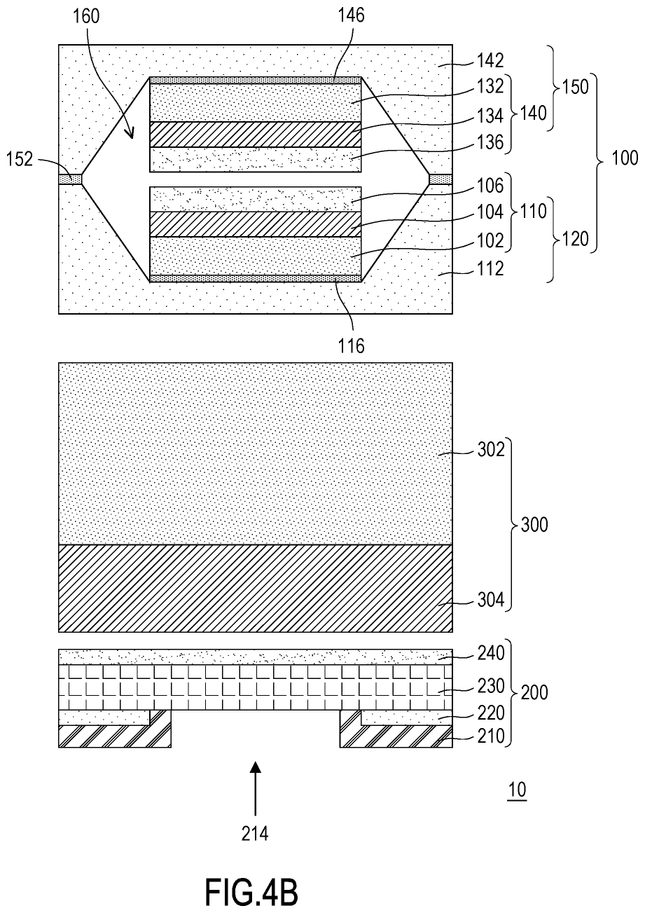

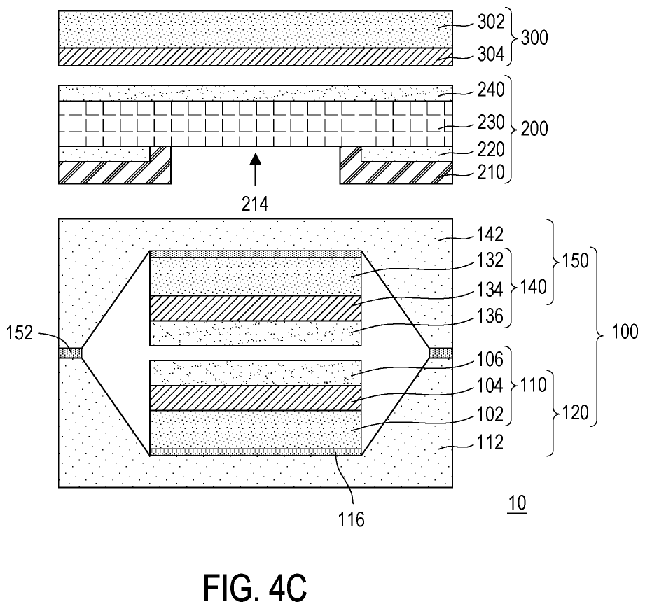

In the above embodiment, it is taken as an example that the film deformation element 100 is disposed between the micro-electric stimulation element 300 and the piezoelectric vibration element 200, but the disclosure is not limited thereto. For example, in one embodiment, as shown in FIG. 4A, the micro-electric stimulation element 300 is, for example, disposed between the film deformation element 100 and the piezoelectric vibration element 200, and the substrate 302 in the micro-electric stimulation element 300, for example, faces the film deformation element 100, while the metal layer 304 in the micro-electric stimulation element 300, for example, faces the piezoelectric vibration element 200. Furthermore, in FIG. 4A, the thickness of the film deformation element 100 is different from the thickness of the micro-electric stimulation element 300 as an example, however, as shown in FIG. 4B, the thickness of the film deformation element 100 can be the same as the thickness of the micro-electric stimulation element 300. In one embodiment, as shown in FIG. 4C, the piezoelectric vibration element 200 is disposed between the micro-electric stimulation element 300 and the film deformation element 100, for example. In this embodiment, the mass damping layer 230 in the piezoelectric vibrating element 200 is, for example, extendable and deformable.

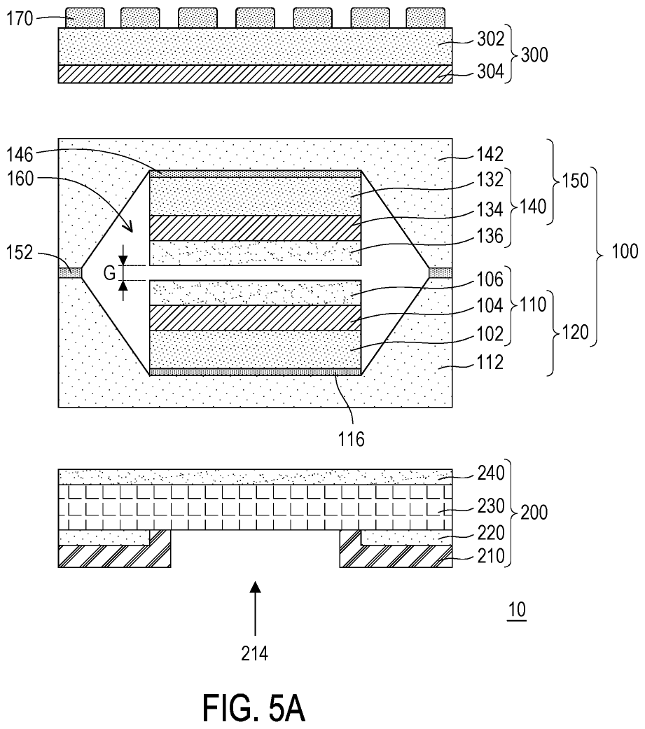

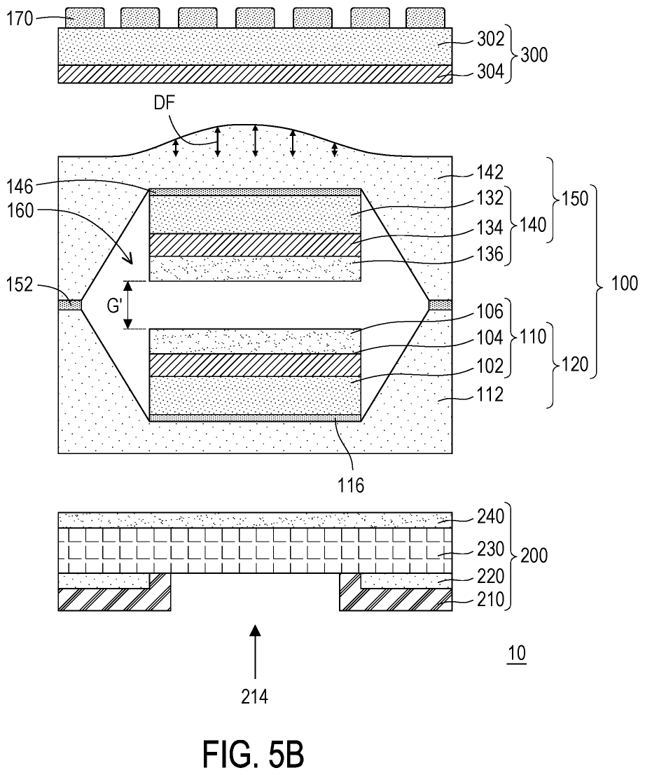

In one embodiment, as shown in FIG. 5A, the film deformation element 100 is, for example, disposed between the micro-electric stimulation element 300 and the piezoelectric vibration element 200. In this embodiment, the protrusion 170 is, for example, disposed on the outermost surface of the haptic feedback unit 10 to increase the haptic experience. For example, the protrusion 170 is disposed on the upper surface of the substrate 302. The material of the protrusion 170 is, for example, polydimethylsiloxane (PDMS), trimethylsiloxy group (Si—SH₃), hexamethyldisiloxane (HMDSO), the like or a combination thereof. The protrusions 170 may respectively have a suitable shape such as a circle or a rectangle. The material of the protrusion 170 can be the same as or different from that of the outermost layer (such as the substrate 302) of the haptic feedback unit 10. In the embodiment where the protrusions 170 are the same material as the outermost layer (such as the substrate 302), the protrusions 170 can be integrally formed with the outermost layer (such as the substrate 302). In this embodiment, the size (such as the width) of the protrusions 170 is, for example, greater than 0.2 μm, and the distance between the protrusions 170 is, for example, greater than 0.2 μm. The protrusions 170 can be arranged regularly or irregularly, for example, the protrusions 170 can be arranged in concentric circles, radiation, array, spiral, the like or a combination thereof.

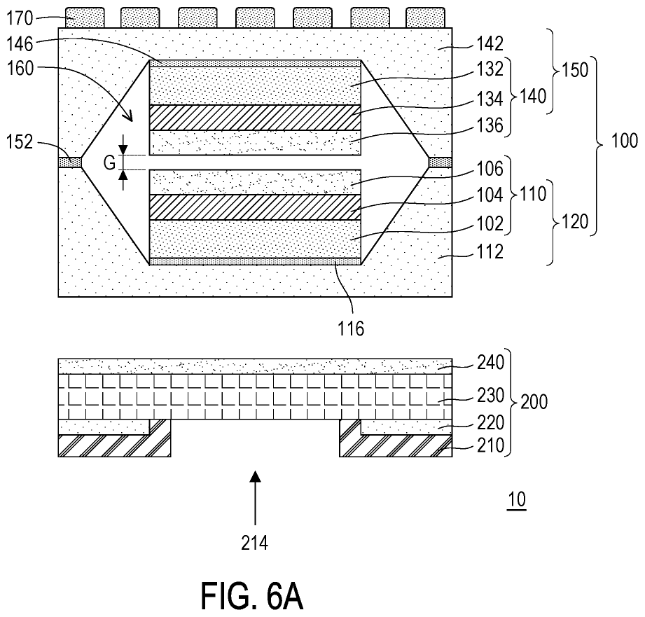

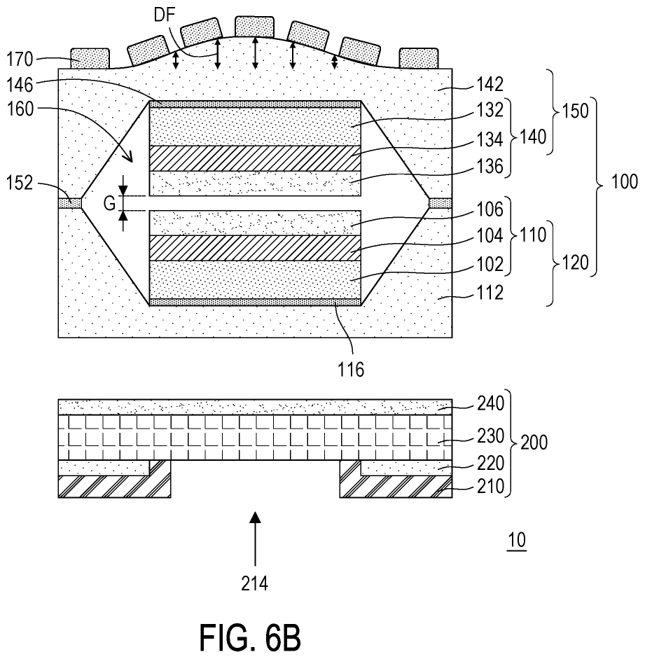

In this embodiment, when there is no voltage, as shown in FIG. 5A, there is a gap G between the first function structure 110 and the second function structure 140 of the film deformation element 100, and when there is a voltage, as shown in FIG. 5B, the second passivation layer 142 of the second function structure 140 can generate a vertical deformation DF, and there is an increased distance G′ between the first function structure 110 and the second function structure 140. In other words, the film deformation element 100 can provide vertical deformation. Moreover, in an embodiment, as shown in FIG. 6A, when the outermost layer of the haptic feedback unit 10 is the passivation layer 142, the protrusion 170 may also be disposed on the upper surface of the passivation layer 142. Furthermore, in this embodiment, in the haptic feedback unit 10 having the protrusion 170, the micro-electric stimulation element 300 can be omitted. In addition, as shown in FIG. 6B, during the deformation of the passivation layer 142, the protrusion 170 on the surface of the passivation layer 142 changes in the vertical position, and the spacing between the protrusions 170 also changes, which can provide different kinds of deformation, thereby increasing haptic feedback.

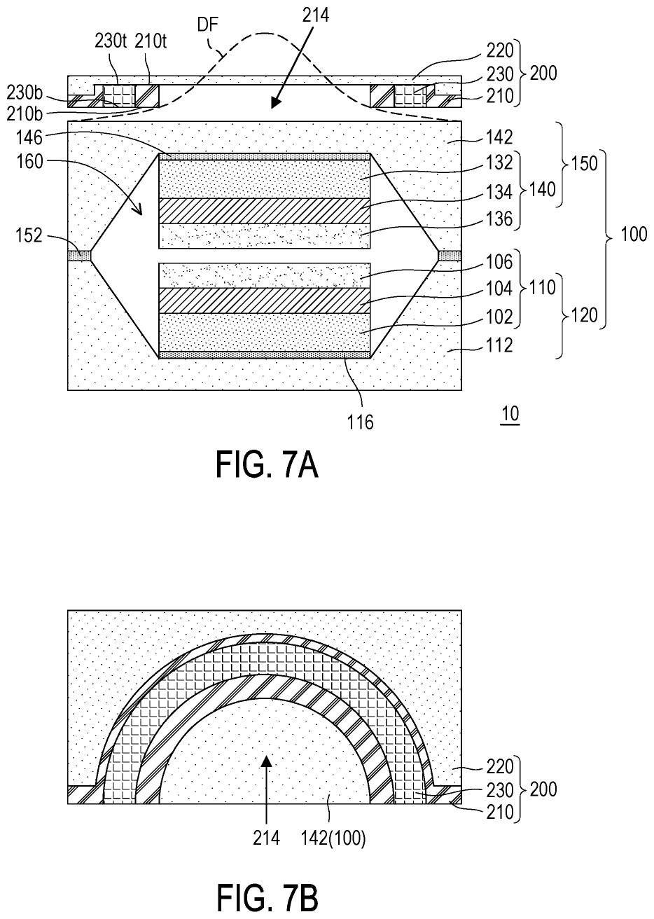

In other embodiments, except that the micro-electric stimulation element 300 can be omitted, the piezoelectric vibration element 200 can also have other configurations. FIG. 7A is a schematic cross-sectional view of a haptic feedback unit according to an embodiment of the disclosure, and FIG. 7B is a partial schematic top view of FIG. 7A. For clarity, the uppermost part of the passivation layer 220 is omitted in FIG. 7B.

Referring to FIG. 7A and FIG. 7B, in this embodiment, the haptic feedback unit 10 includes a film deformation element 100 and a piezoelectric vibrating element 200, and the haptic feedback unit 10 has a hollow design. In this embodiment, the dielectric layer of the piezoelectric vibrating element 200 described above may be omitted. Specifically, the piezoelectric vibrating element 200 includes, for example, a support layer 210, a passivation layer 220 and a mass damping layer 230. The support layer 210 is, for example, ring-shaped and has a hole 214 that exposes the film deformation element 100 therebeneath. The periphery region of the edge of the hole 214 is thus greater than or substantially equal to the periphery region of the function structure 140 therebeneath. The mass damping layer 230 is, for example, ring-shaped and embedded in the support layer 210. In this embodiment, the upper surface 230t of the mass damping layer 230 is substantially coplanar with the upper surface 210t of the support layer 210, and the bottom surface 230b of the mass damping layer 230 is substantially coplanar with the bottom surface 210b of the support layer 210, for example. However, the disclosure is not limited thereto. In another embodiment, the mass damping layer 230 can be embedded in the support layer 210 and partially disposed on the support layer 210. The passivation layer 220 is, for example, disposed on the mass damping layer 230 and the support layer 210 and covers the mass damping layer 230 and the support layer 210. In this embodiment, as shown in FIG. 7A, when there is a voltage, the film deformation element 100 can generate a vertical deformation DF as shown by a dotted line.

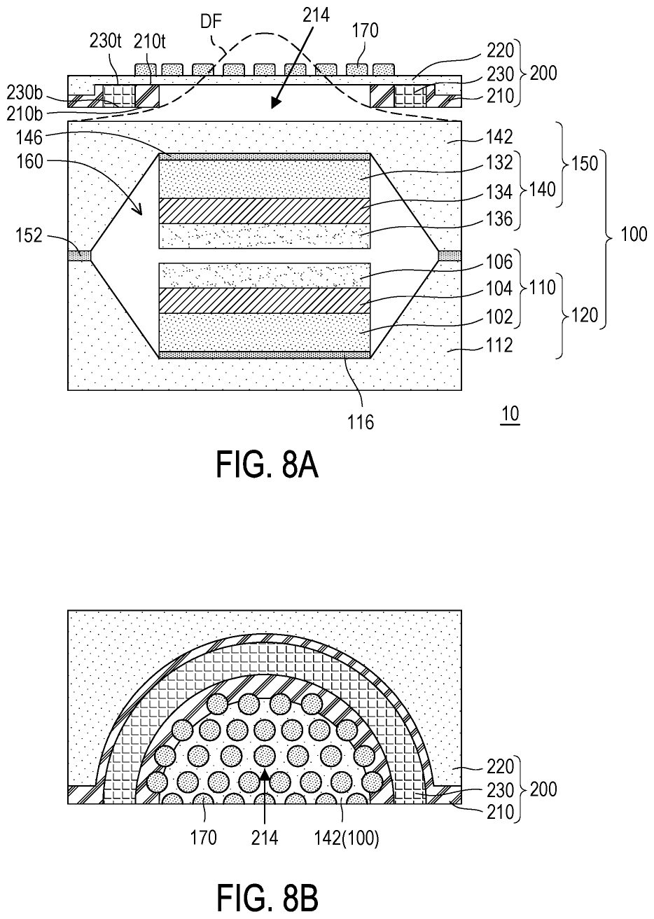

Referring to FIG. 8A and FIG. 8B, in another embodiment, the haptic feedback unit 10 is similar to the haptic feedback unit 10 shown in FIG. 7A and FIG. 7B, but the haptic feedback unit 10 further includes protrusions 170 on the outer surface of the piezoelectric vibrating element 200, to increase the haptic experience. For example, the protrusion 170 is disposed on the upper surface of the passivation layer 220. The material of the protrusion 170 is, for example, polydimethylsiloxane (PDMS), trimethylsiloxy group (Si—SH₃), hexamethyldisiloxane (HMDSO), the like or a combination thereof. The protrusions 170 can be arranged regularly or irregularly, and the protrusions 170 may respectively have a suitable shape such as a circle or a rectangle. In this embodiment, the protrusions 170 are regularly arranged on the upper surface of the passivation layer 220 corresponding to the hole 214, for example. In other words, the protrusions 170 are regularly arranged on the circular area of the upper surface of the passivation layer 220, and the protrusions 170 are arranged corresponding to the function structure 140 of the film deformation element 100 exposed through the hole 214. In this embodiment, as shown in FIG. 8A, when there is a voltage, the film deformation element 100 can generate a vertical deformation DF as shown by a dotted line.

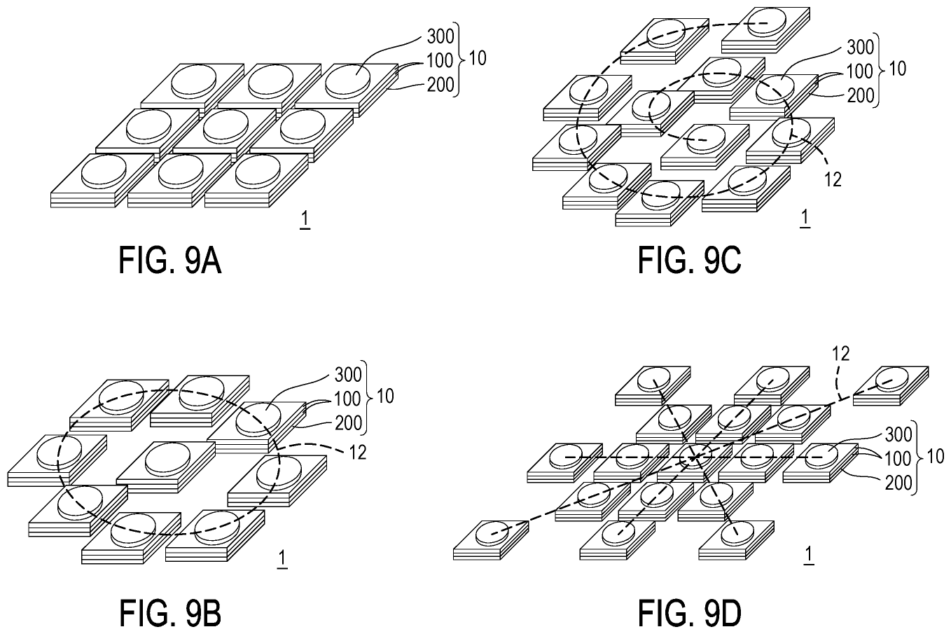

FIG. 9A to FIG. 9D are schematic views of a haptic feedback device according to an embodiment of the disclosure. In this embodiment, the haptic feedback device 1 includes a plurality of aforementioned haptic feedback units 10, wherein the metal layers 104, 134 of one of the first stack 120 (i.e., first function structure 110) and the second stack 150 (i.e., second function structure 140) of the haptic feedback unit 10 are connected in parallel, and the metal layer 104, 134 of the other of the first stack 120 (i.e., first function structure 110) and the second stack 150 (i.e., second function structure 140) are connected in series. For example, the metal layers 134 of the second stack 150 (i.e., second function structure 140) are connected in parallel, and the first metal layers 104 of the first stack 120 (i.e., first function structure 110) are connected in series. In this embodiment, as shown in FIG. 9A, the plurality of haptic feedback units 10 of the haptic feedback device 1 are arranged in an array (such as a 3×3 array), for example. When the haptic feedback device 1 is applied to a high-precision sensing area such as a finger, the total length of a single side of the multiple haptic feedback units 10 arranged in an array is, for example, 20 mm to 50 mm, and the total area of the multiple haptic feedback units 10 arranged in an array is, for example, 20 mm*20 mm-50 mm*50 mm. When the haptic feedback device 1 is applied to a low-precision sensing area such as the back of the hand, the palm of the hand, the upper arm, and the thigh, the total length of a single side of the multiple haptic feedback units 10 arranged in an array is, for example, 70 mm to 150 mm, and the total area of the haptic feedback units 10 arranged in an array is, for example, 70 mm*70 mm-150 mm*150 mm. However, the disclosure is not limited thereto. In other embodiments, the haptic feedback units 10 are, for example, arranged along concentric paths 12 (as shown in FIG. 9B), arranged along spiral paths 12 (as shown in FIG. 9C), or arranged along radial paths 12 (as shown in FIG. 9D).

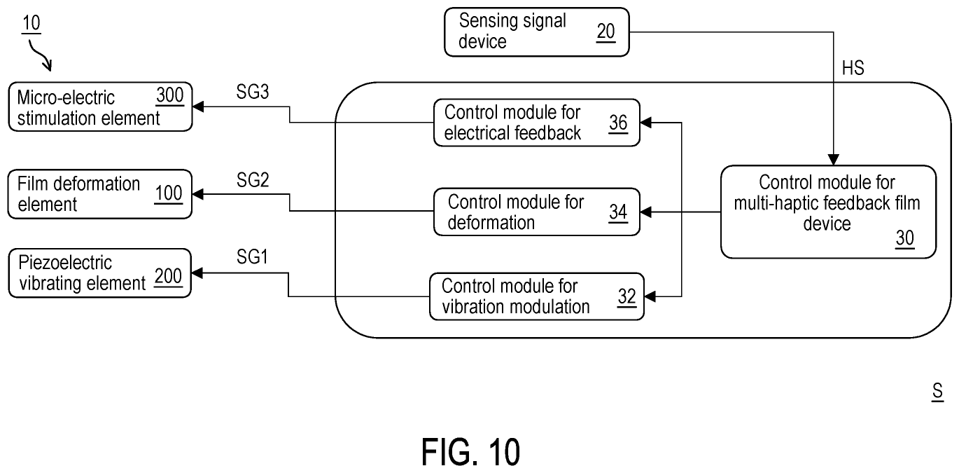

FIG. 10 is a schematic view of a haptic feedback system according to an embodiment of the disclosure. In this embodiment, as shown in FIG. 10, a haptic feedback system S includes the aforementioned haptic feedback unit 10, a sensing signal device 20 electrically connected (such as connected in series) with the haptic feedback unit 10, and a control module for multi-haptic feedback film device 30. The control module for multi-haptic feedback film device 30 includes a control module for vibration modulation 32, a control module for deformation 34 and a control module for electrical feedback 36. In this embodiment, as shown in FIG. 10, the control module for multi-haptic feedback film device 30 receives the incoming sensing signal HS, and the control module for multi-haptic feedback film device 30 communicates with the control module for vibration modulation 32, the control module for deformation 34 and the control module for electrical feedback 36 respectively. The control module for multi-haptic feedback film device 30 can activate the control module for vibration modulation 32, so that the control module for vibration modulation 32 can output a control signal SG1 to the piezoelectric vibration element 200, so that the piezoelectric vibration element 200 generates a corresponding fixed vibration pattern. The control module for deformation 34 can output a control signal SG2, to maintain a fixed deformation of the film deformation element 100. The control module for electrical feedback 36 can output a control signal SG3. At this time, the micro electrical stimulation element 300 can generate a combination of different electrical stimulation parameters in time sequence, thereby providing users with multi-haptic feedback.

In another embodiment, considering continuous time-division multiplexing (TDM) control, a time domain (F(t)) can be added to the sensing signal system. For example, the control module for multi-haptic feedback film device 30 can activate the control module for vibration modulation 32, so that the control module for vibration modulation 32 outputs a control signal F₁(t1) to the piezoelectric vibration element 200, and as a result, the piezoelectric vibration element 200 generates a corresponding fixed vibration pattern. The control module for deformation 34 can output a control signal F₂(t2) to maintain a constant deformation of the film deformation element 100. The control module for electrical feedback 36 can output a control signal F₃(t3), so that the micro-electric stimulation element 300 generates a corresponding micro-electric stimulation amount. At this time, different vibration patterns, different deformation amounts or micro-electric stimulation amounts are continuously generated for feedback combination, thereby providing users with multi-haptic feedback.

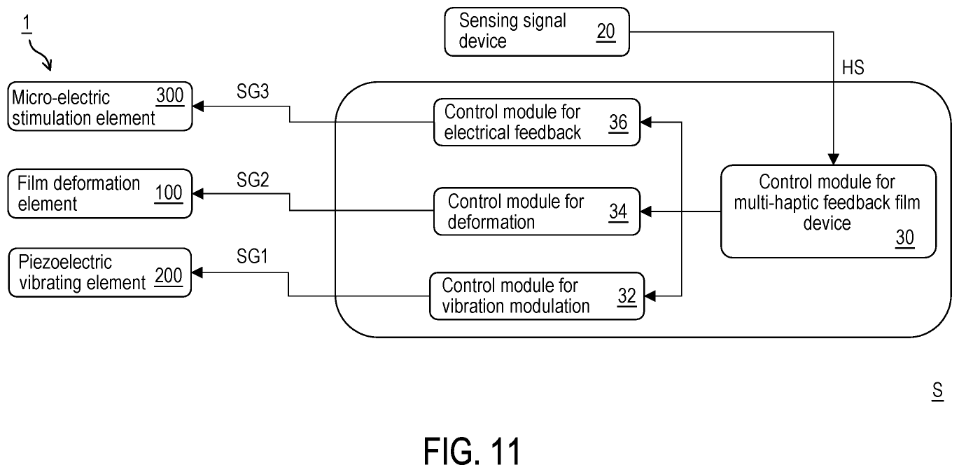

In the above-mentioned embodiments, the control module for multi-haptic feedback film device 30 to control a single haptic feedback unit 10 is exemplified. However, the disclosure is not limited thereto. In other embodiments, as shown in FIG. 11, the control module for multi-haptic feedback film device 30 can also control the haptic feedback device 1 including a plurality of haptic feedback units 10.

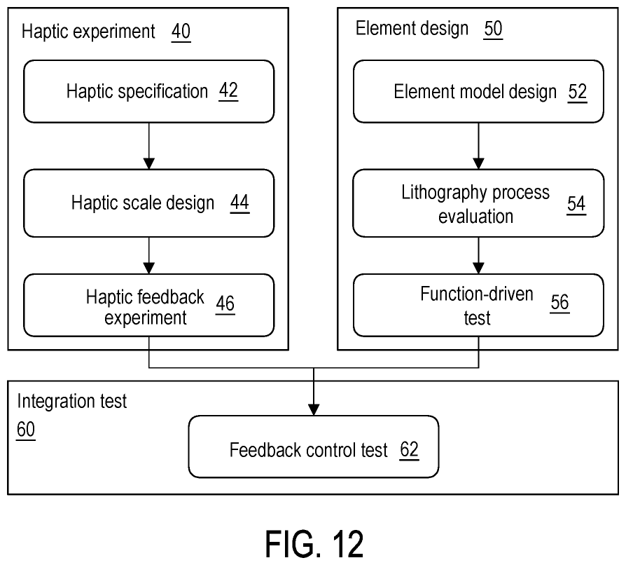

As shown in FIG. 12, in the above-mentioned embodiment, the haptic feedback system (also known as the human factors haptic feedback system) is based on the human factors haptic feedback control and algorithm, including (1) haptic experiment 40: haptic specification 42, haptic scale design 44 and haptic feedback experiment 46; (2) Element design 50: element model design 52, lithography process evaluation 54, and function-driven test 56; and (3) integration test 60: feedback control test 62. In addition, the haptic feedback control system can correct the sensing signal through an algorithm.

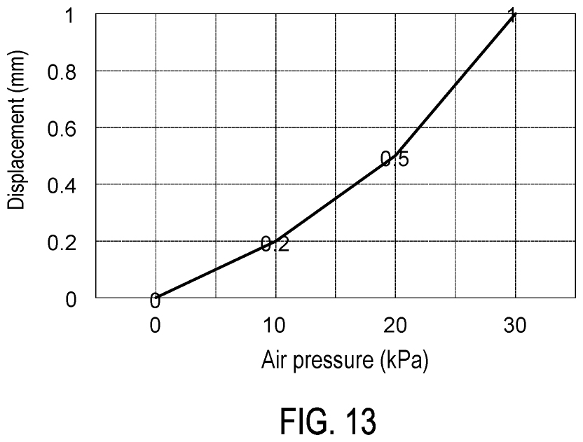

FIG. 13 is a graph showing the relationship between air pressure and displacement of a film deformation element according to an embodiment of the disclosure. From FIG. 13 and Table 1 below, it can be known that the film deformation element can generate corresponding deformation as the air pressure increases.

TABLE 1

| Pressure (kPa) | Displacement (mm) | Force (Fp(N)) |
|---|---|---|
| 0 | 0 | 0 |
| 10 | 0.2 | 0.09 |
| 20 | 0.5 | 0.18 |
| 30 | 1 | 0.27 |

In the embodiment of the disclosure, the haptic feedback device is a vertically stacked haptic feedback structure, which can generate three haptic feedback modes, thereby creating multi-feedback experiences. In addition, the haptic feedback device has a soft film structure, so it can provide requirements for soft wearing comfort, and can increase the space density of haptic feedback through array technology. Since the haptic feedback unit can provide users with multi-haptic feedback, the haptic feedback device including the haptic feedback unit can be widely used in such as center consoles and steering wheels of car, touch screens, wearable clothing and accessories, virtual reality devices, braille machines, hospital surgery, sports equipment, video game devices and other fields that require deformable haptic feedback units.

Although the disclosure has been disclosed above with the embodiments, it is not intended to limit the disclosure. Anyone with ordinary knowledge in the technical field may make some changes and modifications without departing from the spirit and scope of the disclosure. The scope of protection of the disclosure should be defined by the scope of the appended patent application.

What is claimed is:

1. A film deformation element, comprising:
a first stack, comprising:
a first passivation layer;
a first substrate on the first passivation layer;
a first metal layer on the first substrate; and
a first dielectric layer on the first metal layer; and
a second stack, bonded to the first stack to form a sealing space, and comprising:
a second dielectric layer, disposed on the first dielectric layer and facing the first dielectric layer;
a second metal layer on the second dielectric layer;
a second substrate on the second metal layer; and
a second passivation layer on the second substrate.

2. The film deformation element of claim 1 further comprising an adhesion layer, wherein the first passivation layer and the second passivation layer are adhered to each other by the adhesion layer.

3. The film deformation element of claim 1, wherein sidewalls of the first substrate, the first metal layer and the first dielectric layer are substantially flush.

4. The film deformation element of claim 1, wherein the first passivation layer has a housing space, and the first substrate, the first metal layer and the first dielectric layer are sequentially stacked on a bottom surface of the housing space.

5. The film deformation element of claim 4, wherein a sidewall of the first substrate is separated from an inner sidewall of the first passivation layer by the housing space.

6. The film deformation element of claim 1, wherein a material of the first passivation layer and the second passivation layer comprises polydimethylsiloxane (PDMS), trimethylsiloxy group (Si—SH₃), hexamethyldisiloxane (HMDSO) or a combination thereof.

7. The film deformation element of claim 1, wherein a schematic top view of at least one of the first metal layer and the second metal layer is a square, a circle, multiple concentric square rings, multiple concentric circular rings, a spiral, patterns in an array or a combination thereof.

8. A haptic feedback unit, comprising:
a film deformation element, comprising a first stack and a second stack oppositely disposed, wherein the first stack and the second stack respectively include a first passivation layer, a first substrate, a first metal layer and a first dielectric layer; and
a piezoelectric vibration element, comprising a support layer, a second passivation layer and a mass damping layer.

9. The haptic feedback unit of claim 8 further comprising a micro-electric stimulation element, wherein the micro-electric stimulation element comprises a second substrate and a second metal layer on the second substrate.

10. The haptic feedback unit of claim 9, wherein the film deformation element is disposed between the micro-electric stimulation element and the piezoelectric vibration element.

11. The haptic feedback unit of claim 9, wherein the micro-electric stimulation element is disposed between the film deformation element and the piezoelectric vibration element.

12. The haptic feedback unit of claim 9, wherein the piezoelectric vibration element is disposed between the micro-electric stimulation element and the film deformation element.

13. The haptic feedback unit of claim 8, wherein the piezoelectric vibrating element further comprises a second dielectric layer, the support layer includes a hole, the hole exposes the mass damping layer, the second passivation layer is sandwiched between the mass damping layer and the support layer, and the mass damping layer is disposed between the second dielectric layer and the second passivation layer.

14. The haptic feedback unit of claim 8, wherein at least one of the first passivation layer, the first substrate, the first metal layer and the first dielectric layer is provided with a plurality of protrusions thereon.

15. The haptic feedback unit of claim 8, wherein the support layer and the second passivation layer are respectively ring-shaped, and an inner sidewall and a bottom surface of the second passivation layer are in physical contact with the support layer respectively.

16. The haptic feedback unit of claim 8, wherein an upper surface of the support layer is substantially coplanar with an upper surface of the second passivation layer.

17. The haptic feedback unit of claim 8, wherein the mass damping layer comprises a hole corresponding to the film deformation element.

18. A haptic feedback system, comprising:
at least one haptic feedback unit of claim 8;
a sensing signal device, electrically connected to the at least one haptic feedback unit; and
a control module for multi-haptic feedback film device, electrically connected to the at least one haptic feedback unit.

19. The haptic feedback system of claim 18, wherein the control module for multi-haptic feedback film device comprises a control module for vibration modulation and a control module for deformation.

20. The haptic feedback system of claim 18, wherein the at least one haptic feedback unit comprises a plurality of haptic feedback units.
